(19) United States
(12) Patent Application Publication
(10) Pub. No.: US 2025/0351731 A1
(43) Pub. Date: Nov. 13, 2025

(54) METHOD FOR PLANARIZING SURFACE OF SEMICONDUCTOR DEVICE

(71) Applicant: UNITED MICROELECTRONICS CORP., Hsin-Chu City (TW)

(72) Inventors: Chau-Chung Hou, Kaohsiung City (TW); Hsin-Jung Liu, Pingtung County (TW); Tai-Cheng Hou, Tainan City (TW); Ching-Hua Hsu, Kaohsiung City (TW)

(73) Assignee: UNITED MICROELECTRONICS CORP., Hsin-Chu City (TW)

(21) Appl. No.: 18/740,471

(22) Filed: Jun. 11, 2024

(30) Foreign Application Priority Data
May 7, 2024 (TW) 113116760

(51) Int. Cl. H10N 50/01; H10B 61/00

(52) U.S. Cl. CPC H10N 50/01; H10B 61/00

(57) ABSTRACT

A method for planarizing a surface of a semiconductor device includes steps as follows. A substrate is provided. A component is disposed on the substrate. A first dielectric layer is formed to cover the component. The first dielectric layer includes a protruding portion corresponding to the component. A second dielectric layer is formed to cover the first dielectric layer. The second dielectric layer includes a first covering portion disposed on the protruding portion, and a hardness of the second dielectric layer is greater than a hardness of the first dielectric layer. A portion of the first covering portion is etched to form a sidewall structure. The sidewall structure is removed and the second dielectric layer is planarized. A remaining portion of the second dielectric layer and the protruding portion of the first dielectric layer are etched to planarize the first dielectric layer.

### BACKGROUND OF THE INVENTION

### 1. Field of the Invention

The present disclosure relates to the field of semiconductor devices, and more particularly, to a method for planarizing a surface of a semiconductor device.

### 2. Description of the Prior Art

In the manufacturing process of semiconductor devices, it is often necessary to planarize surfaces of the semiconductor devices. When there are defects generated on one of the layers of the semiconductor devices, properties of the next layer will be affected.

Taking the semiconductor device including a magnetoresistive random-access memory (MRAM) as an example, in part of the manufacturing process of the semiconductor device including the MRAM, the MRAM protrudes from the semiconductor device. In the subsequent process of planarizing the dielectric layer covering the MRAM, if the surface of the dielectric layer is accidentally damaged, for example, dents or scratches are formed on the surface of the dielectric layer, it is easy to cause the metal material to fill in the aforementioned dents or scratches during the subsequent metal interconnection process, which may generate bridges between different metal wires and cause short circuits. Accordingly, the performance and/or yield of the semiconductor devices formed later are affected. Therefore, how to improve the method for planarizing the surfaces of the semiconductor devices has become the goal of relevant industries.

### SUMMARY OF THE INVENTION

According to one aspect of the present disclosure, a method for planarizing a surface of a semiconductor device includes steps as follows. A substrate is provided, in which a component is disposed on the substrate. A first dielectric layer is formed to cover the component, in which the first dielectric layer includes a protruding portion corresponding to the component. A second dielectric layer is formed to cover the first dielectric layer, in which the second dielectric layer includes a first covering portion disposed on the protruding portion, and a hardness of the second dielectric layer is greater than a hardness of the first dielectric layer. A portion of the first covering portion is etched to form a sidewall structure. The sidewall structure is removed and the second dielectric layer is planarized. A remaining portion of the second dielectric layer and the protruding portion of the first dielectric layer are etched to planarize the first dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6, FIG. 7 and FIG. 8 are schematic cross-sectional views showing steps of a method for planarizing a surface of a semiconductor device according to an embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical reference signs or similar reference signs are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

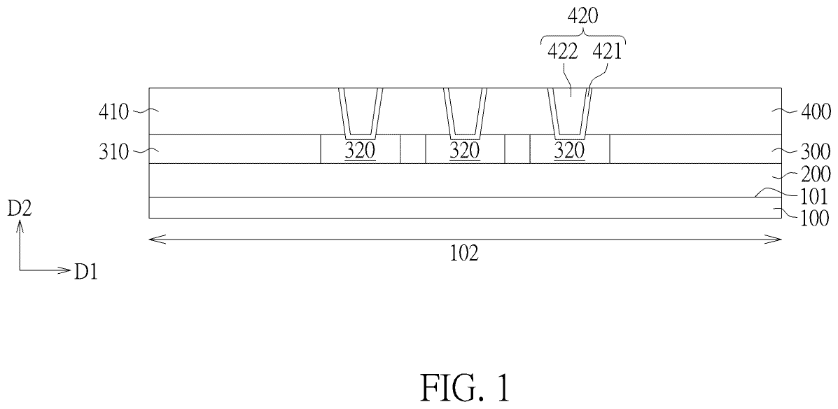

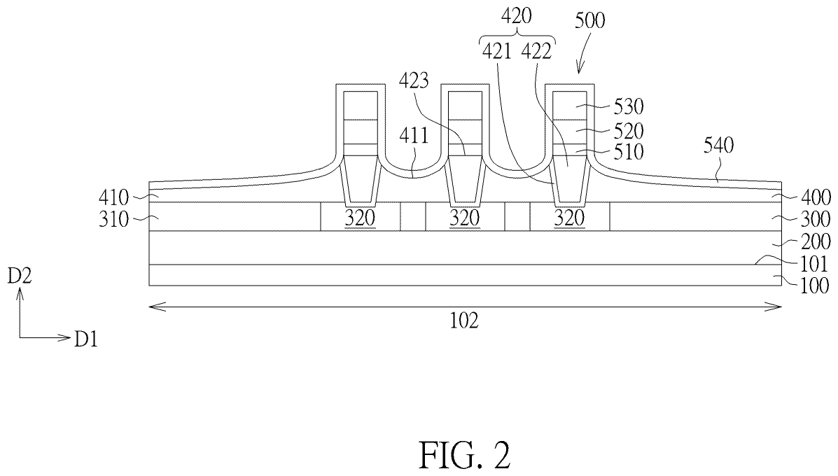

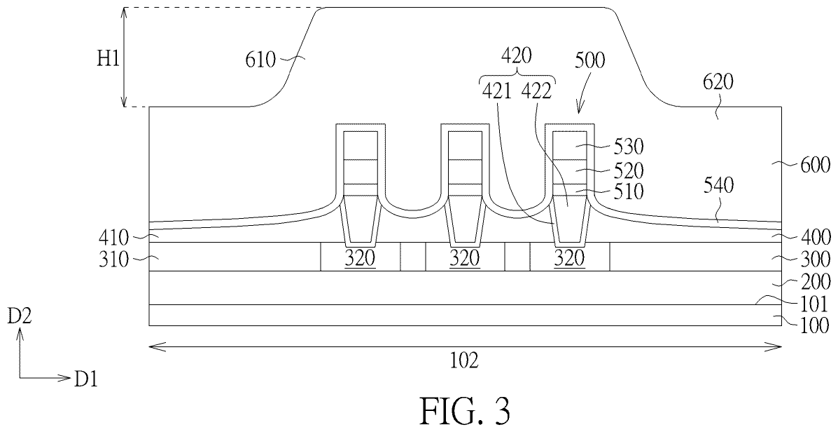

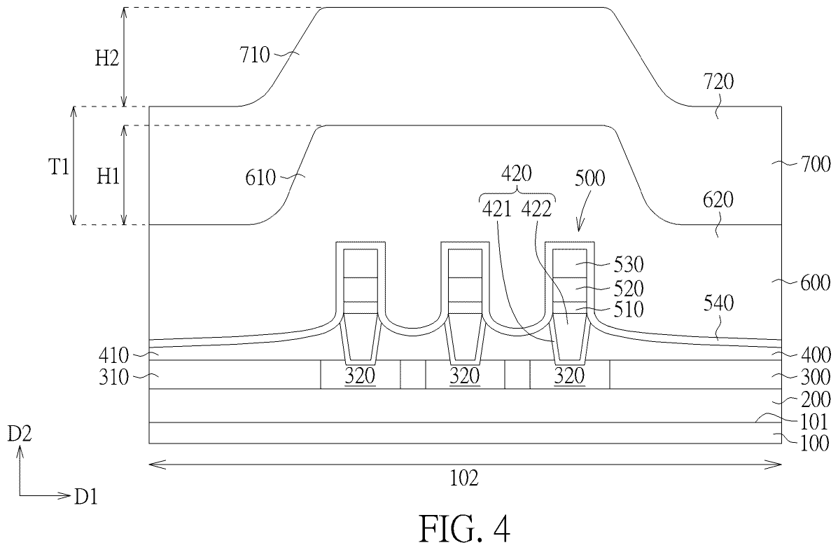

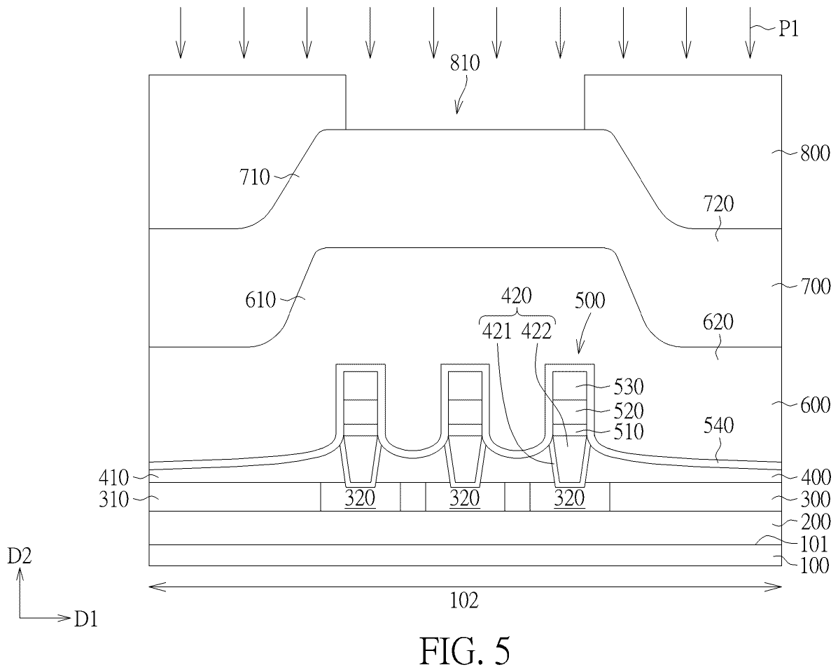

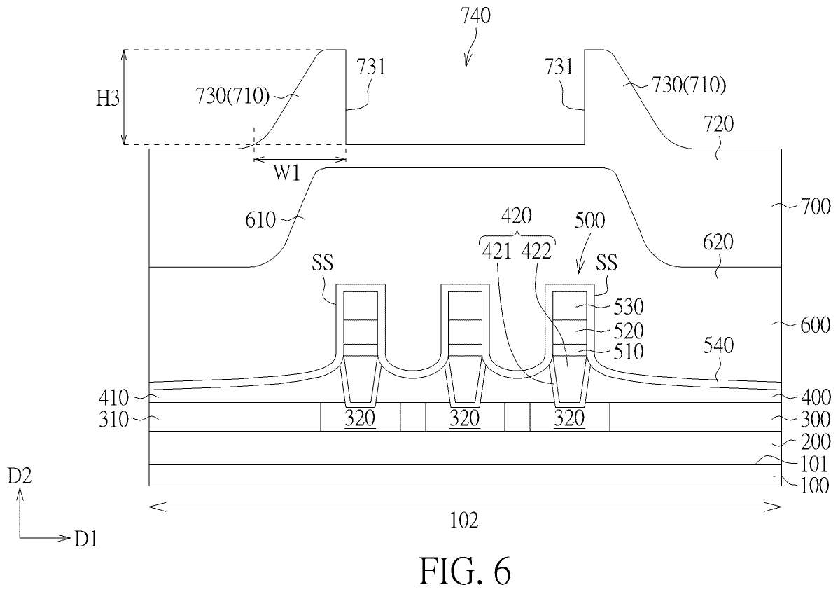

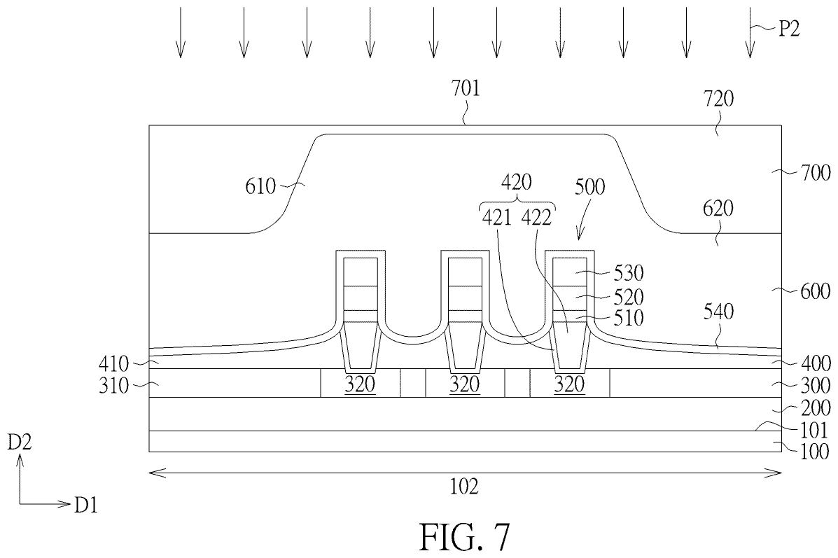

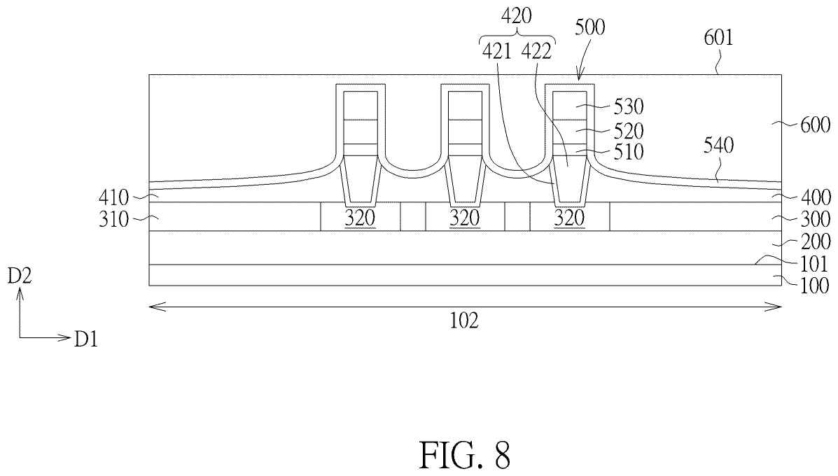

Please refer to FIG. 1 to FIG. 8, which are schematic cross-sectional views showing steps of a method for planarizing a surface of a semiconductor device according to an embodiment of the present disclosure. In FIG. 1, a substrate 100 is provided firstly. The substrate 100 may be a silicon substrate, an epitaxial silicon substrate, a silicon carbide substrate or a silicon on insulator (SOI) substrate. The substrate 100 may define a component region 102 and at least one other region (not shown) adjacent to the component region 102. A component is disposed on the component region 102 of the substrate 100. For example, the component region 102 may be a memory region, which may be disposed with a memory unit such as a MRAM unit. According to an embodiment of the present disclosure, the MRAM unit may be a magnetic tunnel junction (MTJ) component 500 (see FIG. 2), and the other region may be a logic region or a peripheral region, but not limited thereto.

The substrate 100 may include, for example, semiconductor components (not shown) and a dielectric layer 200 covering the aforementioned semiconductor component disposed on the substrate 100. The aforementioned semiconductor components may include various active components or passive components, such as a planar or non-planar metal-oxide semiconductor (MOS) transistor, diodes, capacitors, inductors, and resistors, but not limited thereto. In the dielectric layer 200, a plurality of contact plugs (not shown) may be disposed to be electrically connected with the gate (not shown) and/or the source/drain regions (not shown) of the MOS transistor.

Next, a metal interconnect process may be performed to form a metal interconnect structure 300 on the dielectric layer 200 to be electrically connected with the aforementioned contact plugs. The metal interconnect structure 300 includes an inter-metal dielectric layer 310 and wires 320 embedded in the inter-metal dielectric layer 320. The wire 320 may include, for example, a trench conductor, and a material of the wire 320 may include a metal material, such as aluminum (Al), titanium (Ti), tantalum (Ta), tungsten (W), niobium (Nb), molybdenum (Mo), copper (Cu) or a combination thereof, but not limited thereto. According to an embodiment of the present disclosure, the material of the wire 320 includes copper. Herein, the wire 320 is exemplary a single-layer structure. In other embodiment, the wire 320 may be a multi-layer structure. For example, the wire 320 may further include a barrier layer (not shown), and a material of the barrier layer may include titanium (Ti), tantalum (Ta), titanium nitride (TiN), tantalum nitride (TaN) or a combination thereof, but not limited thereto.

Next, another metal interconnect process may be performed to form a metal interconnect structure 400 on the metal interconnect structure 300 to be electrically connected with the aforementioned wires 320. The metal interconnect structure 400 includes an inter-metal dielectric layer 410 and a contact structure 420 embedded in the inter-metal dielectric layer 410. The contact structure 420 may include, for example, a via conductor. Herein, the contact structure 420 is exemplary a multi-layer structure and includes a barrier layer 421 and a metal layer 422. A material of the barrier layer 421 may include titanium (Ti), tantalum (Ta), titanium nitride (TiN), tantalum nitride (TaN) or a combination thereof, and a material of the metal layer 422 may include aluminum (Al), titanium (Ti), tantalum (Ta), tungsten (W), niobium (Nb), molybdenum (Mo), copper (Cu) or a combination thereof, but not limited thereto. According to an embodiment of the present disclosure, the material of the barrier layer 421 includes titanium nitride, and the material of the metal layer 422 includes tungsten.

A material of each of the inter-metal dielectric layers 310 and 410 may include independently silicon dioxide (SiO₂), tetraethoxysilane (TEOS), silicon nitride (SiN), silicon oxynitride (SiON), silicon nitride carbide (SiCN), nitrogen-doped silicon carbide (NDC), low dielectric constant (low-k) dielectric materials such as fluorinated silica glass (FSG), SiCOH, spin-on glass, ultra-low dielectric constant (ULK) dielectric material, organic polymer dielectric material, plasma-enhanced oxide, or other suitable dielectric materials. The aforementioned ULK dielectric material may include porous dielectric materials, such as, but not limited to, silicon oxycarbide (SiOC). According to an embodiment of the present disclosure, the inter-metal dielectric layer 310 includes an ULK dielectric material, and the inter-metal dielectric layer 410 includes tetraethoxysilane, but not limited thereto.

Next, as shown in FIG. 2, MTJ components 500 are formed on the metal interconnect structure 400. For example, a MTJ material stack (not shown) may be firstly formed on the metal interconnect structure 400. Forming the MTJ material stack may include sequentially forming a bottom electrode material layer (not shown), a MTJ main structure material layer (not shown) and a top electrode material layer (not shown). Next, semiconductor processes, such as photolithography and etching processes are performed to remove a portion of the MTJ material stack to form a plurality of MTJ stacks (not labeled), and then a shielding layer 540 is formed to cover the inter-metal dielectric layer 410 and the top surface and the side surfaces of each of the MTJ stacks to complete the fabrication of the MTJ components 500. The plurality of MTJ components 500 may be arranged along the horizontal direction D1 and may be arranged along another horizontal direction (not shown) to form an array.

Specifically, each of the MTJ components 500 includes the MTJ stack and the shielding layer 540 disposed on the side surfaces and the top surface of the MTJ stack. The MTJ stack may include a bottom electrode layer 510, a MTJ main structure 520 and a top electrode layer 530 from bottom to top. In the process of removing the portion of the MTJ material stack, a portion of the inter-metal dielectric layer 410 is also removed. Therefore, a top surface 411 of the inter-metal dielectric layer 410 is recessed downwardly and is lower than a top surface 423 of each of the contact structures 420.

The material of each of the bottom electrode layer 510 and the top electrode layer 530 may independently include titanium (Ti), tantalum (Ta), titanium nitride (TiN), tantalum nitride (TaN) or a combination thereof. The MTJ main structure 520 may include a pinned layer (not shown), a resistance conversion layer (not shown) and a free layer (not shown) stacked in sequence. Each of the pinned layer and the free layer may independently include a ferromagnetic material, such as iron, cobalt, nickel or an alloy thereof, such as CoFe, NiFe or cobalt-iron-boron (CoFeB), and the material of the resistance conversion layer may include chromium (Cr), ruthenium (Ru), titanium nitride (TiN), tantalum nitride (TaN), aluminum (Al), magnesium (Mg) or magnesium oxide (MgO), but not limited thereto. The material of the shielding layer 540 may include a nitride, such as silicon nitride, but not limited thereto. The relevant principles of the MTJ components 500 are well known in the art and are not described in detail herein. At this stage, the MTJ components 500 protrude from the surface of the semiconductor device (not labeled). Specifically, the MTJ components 500 are disposed on the metal interconnect structure 400. The MTJ components 500 protrude relative to the metal interconnect structure 400 in the vertical direction D2. The aforementioned vertical direction D2, for example, may be perpendicular to the top surface 101 of the substrate 100.

Next, as shown in FIG. 3, a first dielectric layer 600 is formed to cover the MTJ components 500. The first dielectric layer 600 is formed conformally on the shielding layer 540. As mentioned above, the MTJ components 500 protrude from the surface of the semiconductor device (not labeled). Therefore, the first dielectric layer 600 substantially follows the surface morphology of the MTJ components 500 and the shielding layer 540 on the metal interconnect structure 400 and includes a protruding portion 610 and a flat portion 620. The protruding portion 610 is disposed adjacent to the flat portion 620, the protruding portion 610 corresponds to the MTJ components 500, and the flat portion 620 corresponds to the region without the MTJ components 500. The protruding portion 610 may have a protruding height H1 relative to the flat portion 620. According to an embodiment of the present disclosure, the protruding height H1 may range from 1500 angstroms (Å) to 1700 Å. The aforementioned protruding height H1 may be a height of the protruding portion 610 protruding relative to the flat portion 620 in the vertical direction D2. Since the first dielectric layer 600 has the protruding portion 610, the first dielectric layer 600 is required to be planarized. For example, at least the protruding portion 610 is required to be removed to facilitate the formation of other layers on the first dielectric layer 600 in subsequent processes. However, it is difficult to planarize the first dielectric layer 600 by the known planarization processes. Taking the etching process as an example, since the protruding portion 610 and the flat portion 620 are made of the same material, the protruding portion 610 and the flat portion 620 do not have etching selectivity. During the etching process, the heights of the protruding portion 610 and the flat portion 620 are reduced by the same rate and the original surface morphology is remained. Taking the chemical mechanical polishing (CMP) process as another example, the protruding portion 610 is a bulk structure and has a larger polishing area. In practical, it is not easy to remove the protruding portion 610 by the CMP process. That is, the feasibility of directly removing the protruding portion 610 by the CMP process is low, or even if it is feasible, the polishing efficiency is extremely poor. In the present disclosure, the planarization of the first dielectric layer 600 is achieved by improving the method for planarizing the surface of the semiconductor device, and the details are described as follows.

Please refer to FIG. 4, a second dielectric layer 700 is formed to cover the first dielectric layer 600. The second dielectric layer 700 is formed conformally on the first dielectric layer 600. The second dielectric layer 700 substantially follows the surface morphology of the first dielectric layer 600 and includes a first covering portion 710 and a second covering portion 720. The first covering portion 710 is disposed adjacent to the second covering portion 720. The first covering portion 710 is disposed on the protruding portion 610, and the second covering portion 720 is disposed on the flat portion 620. The first covering portion 710 may have a protruding height H2 relative to the second covering portion 720. The aforementioned protruding height H2 may be a height of the first covering portion 710 protruding relative to the second covering portion 720 in the vertical direction D2. The protruding height H2 may be substantially equal to the protruding height H1. A hardness of the second dielectric layer 700 is greater than a hardness of the first dielectric layer 600. According to an embodiment of the present disclosure, a ratio of the hardness of the second dielectric layer 700 to the hardness of the first dielectric layer 600 may range from 4 to 6. For example, the first dielectric layer 600 may include an ULK dielectric material, and the second dielectric layer 700 may include tetraethoxysilane, but not limited thereto. For the properties of the ULK dielectric material and tetraethoxysilane, reference may be made to Table 1 below.

TABLE 1

| | Hardness | Modules | Removing rate of CMP |
|---|---|---|---|
| | (Unit: GPa) | (Unit: GPa) | (Unit: Å/s) |
| tetraethoxysilane | 9.83 | 87.54 | 5-6 |
| ULK dielectric | 1.76 | 19.09 | ≤10 |
| material | | | |

Next, as shown in FIGS. 5 and 6, a portion of the first covering portion 710 is etched to form a sidewall structure 730, which may include steps as follows. First, as shown in FIG. 5, a patterned mask 800 is formed to cover the second dielectric layer 700, in which the patterned mask 800 includes an opening 810 corresponding to a portion of the first covering portion 710, so that the portion of the first covering portion 710 is exposed from the opening 810. Next, an etching process P1 may be performed to etch the portion of the first covering portion 710 exposed from the opening 810, so as to formed a recess 740 in the first covering portion 710, as shown in FIG. 6. The remaining portion of the first covering portion 710 located at two sides of the recess 740 forms the sidewall structure 730. The sidewall structure 730 is disposed adjacent to the recess 740. The sidewall structure 730 may include a vertical surface 731 facing the recess 740. For example, the aforementioned etching process P1 may be a dry etching process, which is beneficial for the sidewall structure 730 to be formed with the vertical surface 731 facing the recess 740. Afterward, the patterned mask 800 is removed.

As shown in FIG. 6, the sidewall structure 730 may have a height H3, and the height H3 may range from 1300 Å to 1500 Å. The sidewall structure 730 may have a thickness W1, and the thickness W1 may range from 0.125 micrometers (μm) to 0.5 μm. The aforementioned height H3 may be a length of the sidewall structure 730 from a bottom end of the recess 740 to a top end of the recess 740 in the vertical direction D2. The aforementioned thickness W1 may be a length of the sidewall structure 730 in the horizontal direction D1. In the embodiment, the thickness W1 of the sidewall structure 730 gradually increases from top to bottom in the vertical direction D2. The aforementioned range of the thickness W1 may refer to the range of the maximum thickness of the sidewall structure 730 in the vertical direction D2. As shown in FIG. 6, the recess 740 overlaps the MTJ components 500 in the vertical direction D2. In addition, in the top view of the semiconductor device (not labeled) shown in FIG. 6, the disposed range of the recess 740 is within the disposed range of the plurality of MTJ components 500. Specifically, in the top view of the semiconductor device shown in FIG. 6, the vertical surface 731 of the sidewall structure 730 is closer to the inside of the semiconductor device than the outer side surface SS of the outermost MTJ component 500.

Next, as shown in FIG. 7, the sidewall structure 730 is removed and the second dielectric layer 700 is planarized to obtain a flat top surface 701. According to an embodiment of the present disclosure, the sidewall structure 730 may be removed and the second dielectric layer 700 may be planarized by a CMP process. Specifically, the sidewall structure 730 of the first covering portion 710 may be removed firstly by the CMP process, and then the CMP process is continued downwardly to thin the thickness of the second dielectric layer 700 on the first dielectric layer 600. It should be noted that the CMP process stops at the second dielectric layer 700 without exposing the first dielectric layer 600. If the CMP process is continued downwardly to expose the first dielectric layer 600, the polishing rate for the first dielectric layer 600 is greater than the polishing rate for the second dielectric layer 700 (for example, reference may be made to the removing rate of CMP for the tetraethoxysilane and the ULK dielectric material shown in Table 1) due to the hardness of the first dielectric layer 600 being less than that of the second dielectric layer 700. As a result, the first dielectric layer 600 may collapse easily by the influence of the CMP process. In addition, as shown in FIG. 4, in the present disclosure, the protruding portion 610 has the protruding height H1, the second dielectric layer 700 has a thickness T1, and the thickness T1 is greater than the protruding height H1. Thereby, the probability of exposing the first dielectric layer 600 when removing the sidewall structure 730 can be reduced, which is beneficial to prevent the first dielectric layer 600 with lower hardness from collapsing due to the influence of the CMP process. The aforementioned thickness T1 may be a length of the second dielectric layer 700 in the vertical direction D2.

Next, please refer back to FIG. 7. An etching process P2 may be performed to etch the remaining portion of the second dielectric layer 700 (i.e., the second dielectric layer 700 is removed completely) and the protruding portion 610 of the first dielectric layer 600 to planarize the first dielectric layer 600. According to an embodiment of the present disclosure, the etching process P2 in this stage is a dry etching process. According to an embodiment of the present disclosure, when etching the remaining portion of the second dielectric layer 700 and the protruding portion 610 of the first dielectric layer 600, an etching rate for the first dielectric layer 600 is equal to an etching rate for the second dielectric layer 700. Thereby, the heights of the dielectric layer (the first dielectric layer 600 and/or the second dielectric layer 700) located in different regions are reduced by the same rate, and a flat top surface 601 can be obtained after the etching process P2 is completed.

According to the above description, in the present disclosure, with the second dielectric layer 700 with the greater hardness being formed on the first dielectric layer 600, a portion of the second dielectric layer 700 being removed to form the sidewall structure 730, and then a planarization process such as a CMP process being performed to planarize the second dielectric layer 700, the polishing area can be reduced by the formation of the sidewall structure 730, so that the CMP process is feasible, and the polishing efficiency can be enhanced. Moreover, the second dielectric layer 700 has the greater hardness, and thus the break of the sidewall structure 730 during the planarization process to damage the top surface 701 of the second dielectric layer 700 can be prevented. Accordingly, the sidewall structure 730 can be planarized gradually to obtain the flat top surface 701. Afterward, with an etching process P2, the first dielectric layer 600 and the second dielectric layer 700 are removed by the same etching rate to obtain the flat top surface 601.

It should be noted that the problem to be solved by the present disclosure is that the dielectric layer (such as the first dielectric layer 600) has a protruding surface morphology due to the component (such as the MTJ component 500) disposed on the substrate 100, which is not beneficial to be removed directly by the etching process or the CMP process. Therefore, in the embodiment, the MTJ components 500 are only exemplary, and the present disclosure is not limited thereto. The MTJ components 500 may be replaced by other components which may cause a dielectric layer (such as the first dielectric layer 600) disposed thereon to have a protruding surface morphology.

Compared a method of directly planarizing the first dielectric layer 600 by the CMP process without forming second dielectric layer 700 with the method according to the present disclosure, because the protruding portion 610 has a greater polishing area than that of the sidewall structure 730, and the protruding portion 610 has a considerable protruding height H1 and a smaller hardness, it is not easy to remove the protruding portion 610 by the CMP process in practice. That is, the feasibility of directly removing the protruding portion 610 by the CMP process is low, or even if it is feasible, the polishing efficiency is extremely poor.

Compared a method of etching a portion of the protruding portion 610 of the first dielectric layer 600 to form a sidewall structure (not shown) and then directly planarizing the first dielectric layer 600 by the CMP process without forming the second dielectric layer 700 with the method according to the present disclosure, although the polishing area of the sidewall structure of the dielectric layer 600 is smaller than that of the protruding portion 610 of the first dielectric layer 600, which allows the CMP to be feasible. However, due to the smaller hardness of the first dielectric layer 600, the sidewall structure is often broken by the polishing external force before the sidewall structure being polished to become flat, and a portion of the first dielectric layer 600 connected with the sidewall structure is often broken along with the sidewall structure, which tends to generate dents and/or scratches on the top surface 601 of the first dielectric layer 600. The yield of subsequent processes tends to be affected by the dents and/or scratches. For example, when a metal interconnection process is performed on the first dielectric layer 600, the metal materials fill in the dents and/or scratches may generate bridges between different metal wires and cause short circuits. Accordingly, the properties and/or yield of the semiconductor devices formed later are affected.

Compared with the prior art, in the method for planarizing a surface of a semiconductor device according the present disclosure, with a dielectric layer with a greater hardness being firstly formed on a surface of the semiconductor device desired to be planarized, and a portion of the dielectric layer with the greater hardness being removed to form a sidewall structure, it is beneficial to reduce the polishing area and the probability of damaging the surface of the semiconductor device desired to be planarized during the polishing process, so as to improve the properties and/or yield of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for planarizing a surface of a semiconductor device, comprising:
providing a substrate, wherein a component is disposed on the substrate;
forming a first dielectric layer to cover the component, wherein the first dielectric layer comprises a protruding portion corresponding to the component;
forming a second dielectric layer to cover the first dielectric layer, wherein the second dielectric layer comprises a first covering portion disposed on the protruding portion, and a hardness of the second dielectric layer is greater than a hardness of the first dielectric layer;
etching a portion of the first covering portion to form a sidewall structure;
removing the sidewall structure and planarizing the second dielectric layer; and
etching a remaining portion of the second dielectric layer and the protruding portion of the first dielectric layer to planarize the first dielectric layer.

2. The method of claim 1, wherein the protruding portion has a protruding height, the second dielectric layer has a thickness, and the thickness is greater than the protruding height.

3. The method of claim 1, wherein etching the portion of the first covering portion comprises forming a recess, and the sidewall structure is disposed adjacent to the recess.

4. The method of claim 3, wherein the sidewall structure comprises a vertical surface facing the recess.

5. The method of claim 3, wherein etching the portion of the first covering portion comprises:
forming a patterned mask to cover the second dielectric layer, wherein the patterned mask comprises an opening corresponding to the portion of the first covering portion; and
etching the portion of the first covering portion to form the recess.

6. The method of claim 1, wherein the portion of the first covering portion is etched by a dry etching process.

7. The method of claim 1, wherein the sidewall structure is removed and the second dielectric layer is planarized by a chemical mechanical polishing process.

8. The method of claim 1, wherein when etching the remaining portion of the second dielectric layer and the protruding portion of the first dielectric layer, an etching rate for the first dielectric layer is equal to an etching rate for the second dielectric layer.

9. The method of claim 1, wherein a ratio of the hardness of the second dielectric layer to the hardness of the first dielectric layer ranges from 4 to 6.

10. The method of claim 1, wherein the first dielectric layer comprises an ultra-low dielectric constant dielectric material.

11. The method of claim 1, wherein the second dielectric layer comprises tetraethoxysilane.

12. The method of claim 1, wherein the component comprises a magnetic tunnel junction component.

13. The method of claim 1, wherein the protruding portion has a protruding height ranging from 1500 Å to 1700 Å.

14. The method of claim 1, wherein the sidewall structure has a height ranging from 1300 Å to 1500 Å.

15. The method of claim 1, wherein the sidewall structure has a thickness ranging from 0.125 μm to 0.5 μm.
